(19) United States
(12) Patent Application Publication
(10) Pub. No.: US 2006/0278888 A1
(43) Pub. Date: Dec. 14, 2006

(54) Vertically-structured nitride semiconductor light emitting diode

(75) Inventors: Dong Woo Kim, Cheongju (KR); Hee Seok Choi, Seoul (KR); Seok Beom Choi, Daejeon (KR); Tae Jun Kim, Pyeongtaek (KR)

Correspondence Address: MCDERMOTT WILL & EMERY LLP, 600 13TH STREET, N.W., WASHINGTON, DC, 20005-3096, US

(73) Assignee: SAMSUNG ELECTRO-MECHANICS CO., LTD.

(21) Appl. No.: 11/443,155

(22) Filed: May 31, 2006

(30) Foreign Application Priority Data
May 31, 2005 (KR) 10-2005-0045872

(51) Int. Cl. H01L 33/00

(52) U.S. Cl. 257/103

(57) ABSTRACT

The present invention relates to a vertically-structured nitride semiconductor light emitting diode. The vertically-structured nitride semiconductor light emitting diode includes an n-type electrode; an n-type nitride semiconductor layer that is formed on the lower surface of the n-type electrode and on which surface texturing with a diffraction grating structure is formed, the diffraction grating structure composed of more than one line; an active layer that is formed on the lower surface of the n-type nitride semiconductor layer; a p-type nitride semiconductor layer that is formed on the lower surface of the active layer; and a p-type electrode that is formed on the lower surface of the p-type nitride semiconductor layer.

### CROSS-REFERENCE TO RELATED APPLICATIONS

The application claims the benefit of Korea Patent Application No. 2005-0045872 filed with the Korea Industrial Property Office on May 31, 2005, the disclosure of which is incorporated herein by reference.

### BACKGROUND OF THE INVENTION

1. Field of the Invention

The present invention relates to a vertically-structured nitride semiconductor light emitting diode which has high external quantum efficiency.

2. Description of the Related Art

In general, a light emitting diode (hereinafter, referred to as ‘LED’), which has such characteristics as a small size, low power consumption, high reliability, and the like, is widely used as a light source for display. As a material of the LED, compound semiconductors formed of a nitride and an arsenide of the group III-V such as GaAs, AlGaAs, GaN, InGaN, or AlGalnP are used. With a material of the compound semiconductor being changed, red, blue, and green light emitting sources can be constructed, thereby realizing various colors of light.

On the other hand, efficiency of the light generated by a nitride semiconductor LED is divided into internal quantum efficiency and external quantum efficiency. The internal quantum efficiency depends on the design or quality of an active layer, and the external quantum efficiency depends on how much the light generated from the active layer comes outside the nitride semiconductor LED.

Now, the structure of a nitride semiconductor LED according to the related art for improving the external quantum efficiency will be described in detail with reference to FIGS. 1 to 4.

FIG. 1 is a cross-sectional view illustrating the structure of a horizontally-structured nitride semiconductor LED according to the related art.

Referring to FIG. 1, the LED according to the related art includes a sapphire substrate, a GaN buffer layer (not shown), an n-type GaN layer 102, an InGaN active layer 103, and a p-type GaN layer 104, which are sequentially crystal-grown. Portions of the InGaN active layer 103 and p-type GaN layer 104 are removed by etching, so that a groove 108 exposing a portion of the n-type GaN layer 102 is formed.

On the upper surface of the p-type GaN layer, surface texturing is formed to have a predetermined shape. On the n-type GaN layer 102 exposed on the bottom surface of the groove 108, an n-type electrode 106 is formed. On the p-type GaN layer 104, a transparent electrode 105 and a p-type electrode 107 are sequentially formed.

Such an LED operates as follows.

The holes injected through the p-type electrode 107 spread transversely from the p-type electrode 107. The holes are injected from the p-type GaN layer 104 to the InGaN active layer 103. The electrons injected through the n-type electrode 106 are injected from the n-type GaN layer 102 to the InGaN active layer 103. Within the InGaN active layer 103, the holes and electrons are recombined to thereby emit light. The light is discharged outside the LED through the transparent electrode 105.

In the structure of the LED according to the related art, if light is incident on a portion where the surface texturing is formed, the incident angle of the light can become smaller than a critical refraction angle by the surface texturing with a predetermined shape which is formed on the surface of the p-type GaN layer, even though an angle of the light from a normal line with respect to the interface between the plane portion of the transparent electrode 105 and the air is larger than a critical refraction angle. Therefore, it is highly likely that the light generated by the active layer is not totally reflected but discharged outside the LED, thereby improving the external quantum efficiency.

In such an LED according to the related art, the surface texturing which emits light is formed by using a lithographic process and plasma dry etching process, in order to improve the external quantum efficiency.

However, since the surface texturing is formed on the surface of the p-type GaN layer through the plasma dry etching, the active layer and the surface of the p-type GaN layer can be damaged by the plasma, thereby increasing the contact resistance of the p-type GaN layer.

In order to solve such problems, a technique has been proposed, in which surface texturing is formed on the surface of an n-type GaN layer of an LED, as shown in FIGS. 2 and 3. FIG. 2 is a cross-sectional view illustrating the structure of a vertically-structured nitride semiconductor LED according to the related art. FIG. 3 is a plan view illustrating the structure where the surface texturing of the vertically-structured nitride semiconductor LED according to the related art is formed. FIG. 4 is a graph for explaining the problems of the vertically-structured nitride semiconductor LED shown in FIG. 2.

In the LED shown in FIG. 2, the surface texturing 300 with a predetermined shape, which has been formed on the surface of the p-type GaN layer in the related art, is formed on the surface of an n-type GaN layer which is exposed by removing a sapphire substrate through a laser lift-off (hereinafter, referred to as ‘LLO’) method.

In other words, the surface texturing 300 for improving the external quantum efficiency is formed on the n-type GaN layer having a large thickness, not on the p-type GaN layer having a small thickness, through a lithographic and plasma dry etching process. Therefore, the p-type GaN layer is prevented from being damaged, and simultaneously the external quantum efficiency can be improved.

In such an LED according to the related art, the surface texturing for improving the external quantum efficiency is formed to have convex or concave patterns such as circles, rectangles, or hexagons, as shown in FIG. 3. As such, when the surface texturing is formed to have the plurality of convex or concave patterns, and when the distance d between the patterns is lengthened, some of the light generated by the active layer is totally reflected in a region corresponding to the width therebetween, so that the external quantum efficiency is reduced as found in FIG. 4. Therefore, since all the light generated by the active layer cannot be discharged outside the LED, there is a limit in increasing the external quantum efficiency.

### SUMMARY

An advantage of the present invention is that it provides a vertically-structured nitride semiconductor light emitting diode having a surface texturing structure which can enhance external quantum efficiency without a p-type nitride semiconductor layer being damaged.

Additional aspects and advantages of the present general inventive concept will be set forth in part in the description which follows and, in part, will be obvious from the description, or may be learned by practice of the general inventive concept.

According to an aspect of the invention, a vertically-structured nitride semiconductor LED includes an n-type electrode; an n-type nitride semiconductor layer that is formed on the lower surface of the n-type electrode and on which surface texturing with a diffraction grating structure is formed, the diffraction grating structure composed of more than one line; an active layer that is formed on the lower surface of the n-type nitride semiconductor layer; a p-type nitride semiconductor layer that is formed on the lower surface of the active layer; and a p-type electrode that is formed on the lower surface of the p-type nitride semiconductor layer.

Preferably, in the vertically-structured nitride semiconductor LED, the n-type electrode is formed so as not to be overlapped with the surface texturing with the diffraction grating structure. That is because, if the n-type electrode is formed to be overlapped with the surface texturing with a diffraction grating structure, the contact surface of the n-type electrode has roughness due to the surface texturing. Accordingly, electrical characteristics are deteriorated, that is, the resistance of electric current flowing into the n-type nitride semiconductor layer through the n-type electrode increases.

Preferably, in the vertically-structured nitride semiconductor LED, the n-type electrode is preferably positioned in the center of the n-type nitride semiconductor layer, which makes it possible to uniformize the distribution of currents transmitted to the lower semiconductor layer through the n-type electrode.

Preferably, in the vertically-structured nitride semiconductor LED, the line of the diffraction grating structure formed on the surface of the n-type nitride semiconductor layer is composed of any one line selected from a group composed of a straight line, a curved line, and a single closed curve, and the width of the end portion of the line is the same as or larger than the wavelength of a light emitting source which is emitted by the active layer, in order to enhance a refraction characteristic of the light emitted from the LED. As such, if the light emitted from the LED has an excellent refraction characteristic, an amount of light which is diffusely reflected and disappears inside the LED due to a low refraction characteristic of the light can be minimized.

Preferably, the vertically-structured nitride semiconductor LED further includes a supporting substrate formed on the lower surface of the p-type electrode so as to support the vertically-structured nitride semiconductor LED.

Preferably, the vertically-structured nitride semiconductor LED further includes a contact layer formed on the interface between the p-type electrode and the supporting substrate, in order to enhance the adherence between the p-type electrode and the supporting substrate.

Preferably, the vertically-structured nitride semiconductor LED further includes a contact layer formed on the interface between the p-type nitride semiconductor layer and the p-type electrode.

According to another aspect of the invention, a vertically-structured nitride semiconductor light emitting diode includes an n-type electrode; an n-type nitride semiconductor layer that is formed on the lower surface of the n-type electrode and on which surface texturing with a mesh structure, where more than two lines intersect each other at more than one point, is formed; an active layer that is formed on the lower surface of the n-type nitride semiconductor layer; a p-type nitride semiconductor layer that is formed on the lower surface of the active layer; and a p-type electrode that is formed on the lower surface of the p-type nitride semiconductor layer.

Preferably, in the vertically-structured nitride semiconductor LED, the n-type electrode is formed so as not to be overlapped with the surface texturing with a mesh structure.

As such, the surface texturing for improving the external quantum efficiency is formed on the surface of the n-type nitride semiconductor layer which comes in contact with the n-type electrode. The surface texturing is not formed to have convex or concave patterns such as circles, rectangles, or hexagons, but is formed to have a diffraction grating structure or mesh structure in which the distance between the patterns is minimized, thereby maximizing the external quantum efficiency of the LED.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is a perspective view illustrating the structure of a vertically-structured nitride semiconductor LED according to the related art;

FIG. 2 is a perspective view illustrating the structure of the vertically-structured nitride semiconductor LED according to the related art;

FIGS. 3A-3C are plan views illustrating a structure where the surface texturing of another vertically-structured nitride semiconductor LED according to the related art is formed;

FIG. 4 is a graph for explaining the problems of the vertically-structured nitride semiconductor LED shown in FIG. 2;

FIG. 5 is a perspective view illustrating the structure of a vertically-structured nitride semiconductor LED according to an embodiment of the present invention;

FIG. 6 is a plan view illustrating a structure where the surface texturing of the vertically-structured nitride semiconductor LED shown in FIG. 5 is formed;

FIGS. 7A-7E are plan views illustrating a structure where the surface texturing with a diffraction grating structure of another vertically-structured nitride semiconductor LED according to an embodiment of the invention is formed;

FIGS. 8A-8G are plan views illustrating a structure where the surface texturing with a mesh structure of another vertically-structured nitride semiconductor LED according to an embodiment of the invention is formed;

FIG. 9 is a graph comparatively showing the external quantum efficiency of the vertically-structured nitride semiconductor LEDs shown in FIGS. 2 and 5; and

FIGS. 10A-10F are plan views illustrating a structure where an n-type electrode and surface texturing of another vertically-structured nitride semiconductor LED according to an embodiment of the invention are disposed.

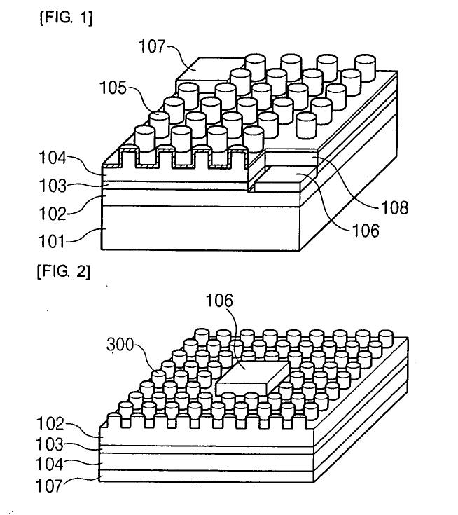

### DETAILED DESCRIPTION

Reference will now be made in detail to the embodiments of the present general inventive concept, examples of which are illustrated in the accompanying drawings, wherein like reference numerals refer to the like elements throughout. The embodiments are described below in order to explain the present general inventive concept by referring to the figures.

Hereinafter, preferred embodiments of the present invention will be described in detail with reference to the accompanying drawings so that the present invention can be easily embodied by a person with an ordinary skill in the art.

In the drawings, the thickness of each layer is enlarged in order to clearly illustrate various layers and regions.

Now, a vertically-structured nitride semiconductor LED according to an embodiment of the present invention will be described in detail with reference to FIGS. 5 to 10.

First, the vertically-structured nitride semiconductor LED according to the embodiment of the invention will be described in detail with reference to FIGS. 5 and 6.

FIG. 5 is a perspective view illustrating the structure of the vertically-structured nitride semiconductor LED according to an embodiment of the invention. FIG. 6 is a plan view illustrating a structure where the surface texturing of the vertically-structured nitride semiconductor LED shown in FIG. 5 is formed.

Referring to FIGS. 5 and 6, an n-type electrode 106 formed of Ti/Al or the like is formed on the uppermost portion of the vertically-structured nitride semiconductor LED according to the invention.

On the lower side of the n-type electrode 106, an n-type nitride semiconductor layer 102, an active layer 103, and a p-type nitride semiconductor layer 104 are sequentially laminated.

In this case, the n-type electrode may be formed anywhere on the n-type nitride semiconductor layer. Preferably, however, the n-type electrode is formed on the center of the n-type nitride semiconductor layer, in order to uniformize the distribution of electric currents transmitted to the n-type nitride semiconductor through the n-type electrode.

The n-type or p-type nitride semiconductor layer 102 or 104 can be composed of a GaN layer or GaN/AlGaN layer which is doped with a conductive impurity. The active layer 130 can be composed of an InGaN/GaN layer so as to have a multi-quantum well structure.

### FIRST EMBODIMENT

On the n-type nitride semiconductor layer 102 which comes in contact with the n-type electrode 106 according to a first embodiment of the invention, surface texturing 300 with a diffraction grating structure is formed so that more than one line is periodically arranged at a predetermined distance in only one direction, as shown in FIG. 6.

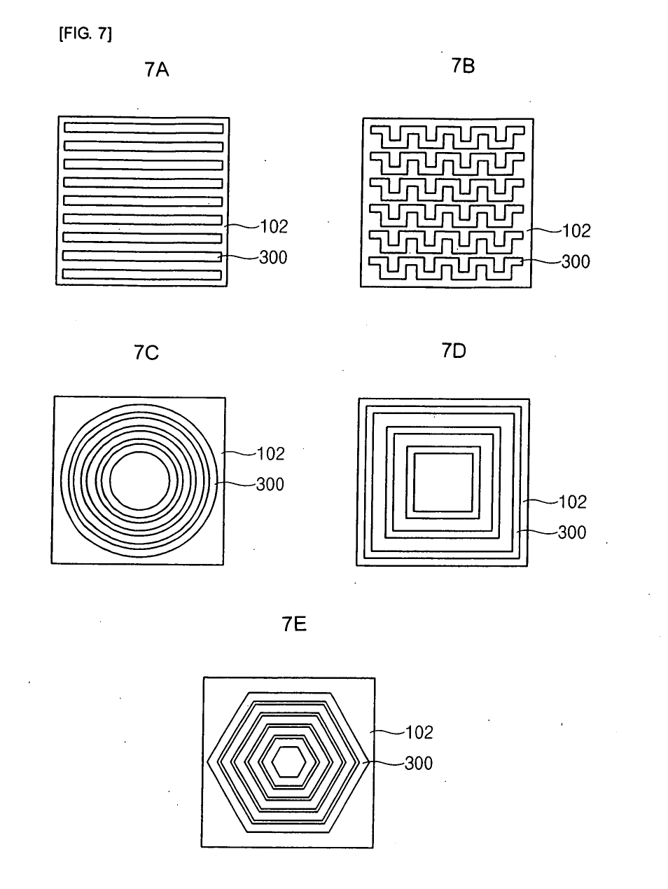

The line composing the surface texturing 300 with a diffraction grating structure can be formed not only in a straight line, but also in a curved line or a single closed curve. As shown in FIG. 7, the surface texturing 300 can have a diffraction grating structure formed in various shapes. Further, in the first embodiment of the invention, the side surface of the end portion of the line is formed in a rectangular shape. Without being limited thereto, however, the side surface of the end portion thereof can be formed in a semi-circular shape or a triangle shape.

### SECOND EMBODIMENT

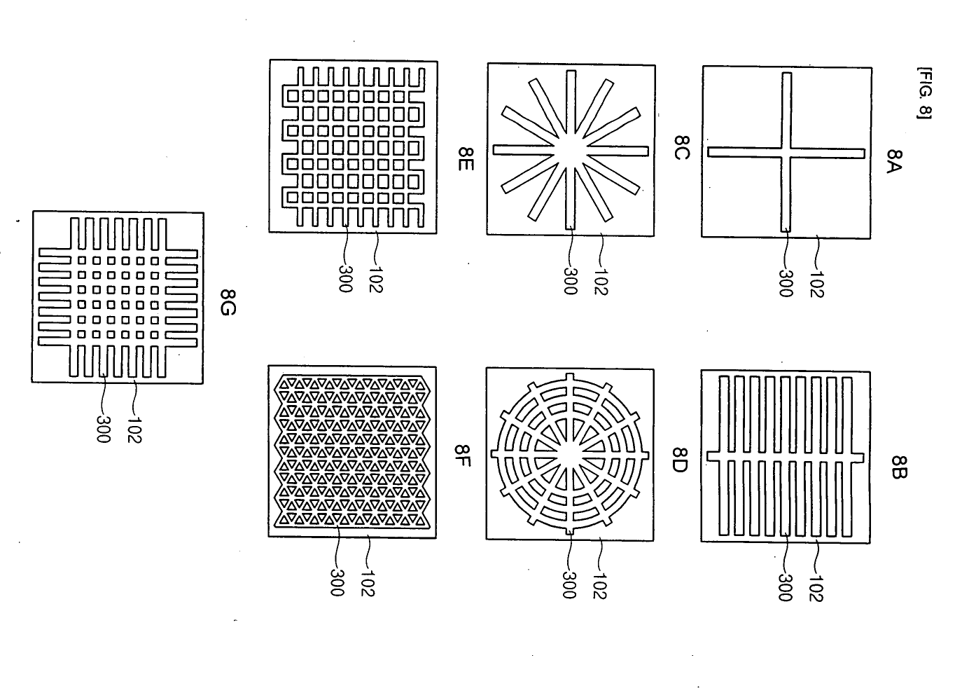

According to a second embodiment of the invention, surface texturing composed of lines can be formed to have a variety of mesh structures where more than two lines intersect each other at more than one point, as shown in FIG. 8. The line composing the mesh structure can be formed not only in a straight line, but also in a curved line or a single closed curve, similar to the line composing the diffraction grating structure of the first embodiment. Further, in the second embodiment of the invention, the side surface of the end portion of the line is formed in a rectangular shape. Without being limited thereto, however, the side surface of the end portion thereof can be formed in a semi-circular shape or a triangle shape.

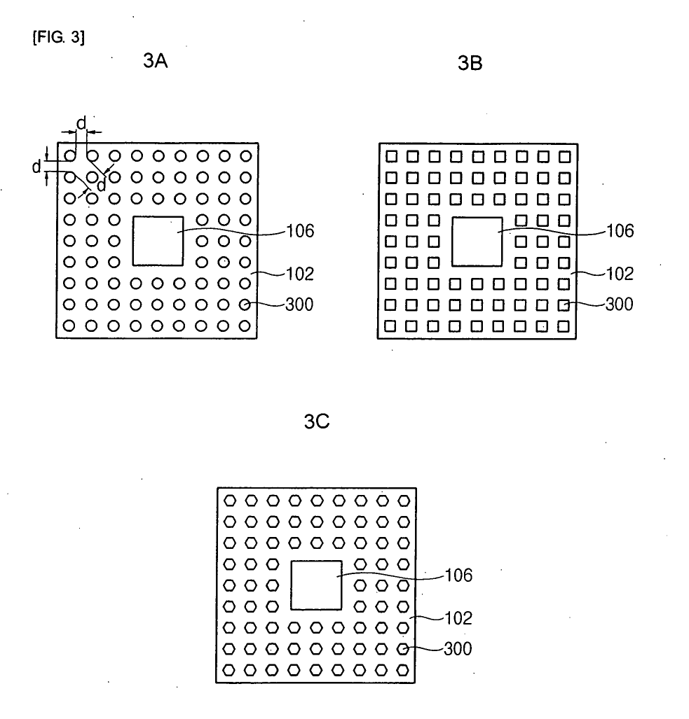

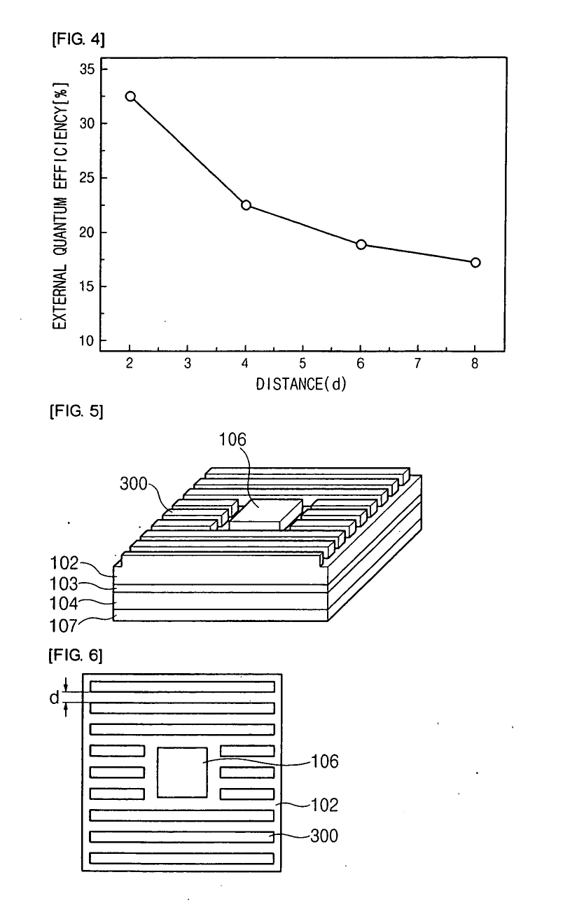

In other words, if the surface texturing 300 with the diffraction grating structure or mesh structure according to the first or second embodiment is composed of at least more than one line among a straight line, a curved line, and a single curved line, the distance d between patterns can be completely removed, compared with the surface texturing (refer to FIG. 3) of convex or concave patterns such as circles, rectangles, or hexagons according to the related art, which is composed of one line and is formed within the same unit area. Therefore, higher quantum efficiency can be secured than in the surface texturing according to the related. That can be found through a graph of FIG. 4 showing that the smaller the distance d between patterns, the larger the external quantum efficiency.

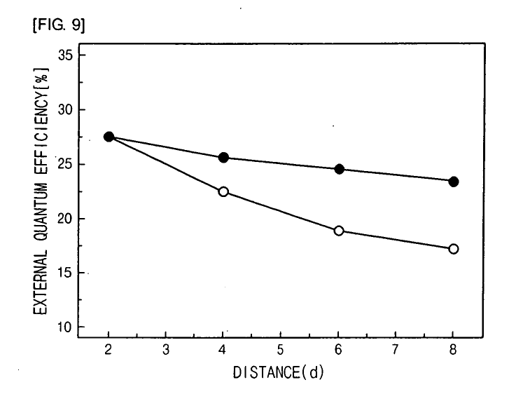

On the other hand, since the surface texturing 300 according to the embodiment of the invention is composed of more than one line, a predetermined distance d is defined between the lines. However, compared with the surface texturing (refer to FIG. 3) composed of convex or concave patterns with a predetermined shape according to the related art which are formed in the same unit area, the external quantum efficiency of the surface texturing (refer to FIG. 8) composed of lines according to the embodiment of the invention decreases more slowly as the distance d between patterns increases as shown in FIG. 9, even though the same distance d is defined. In the graph of FIG. 9, ∘ (circle) represents the quantum efficiency of the surface texturing according to the related art, and ● (solid) represents the quantum efficiency of the surface texturing according to the present invention.

The width of the end portion of the line of the surface texturing 300 is the same as or larger than the wavelength of a light emitting source which is emitted by the active layer 103, in order to improve a refraction characteristic of the light emitted outside from the active layer 103. For example, when a light emitting source emitted by the active layer 103 is blue, the end portion of the line has a width of 400 to 480 nm or larger than 480 nm.

As such, if the light emitted outside from the active layer 103 has an excellent refraction characteristic, an amount of light which is diffusely reflected and disappears inside the LED due to a low refraction characteristic of the light can be minimized.

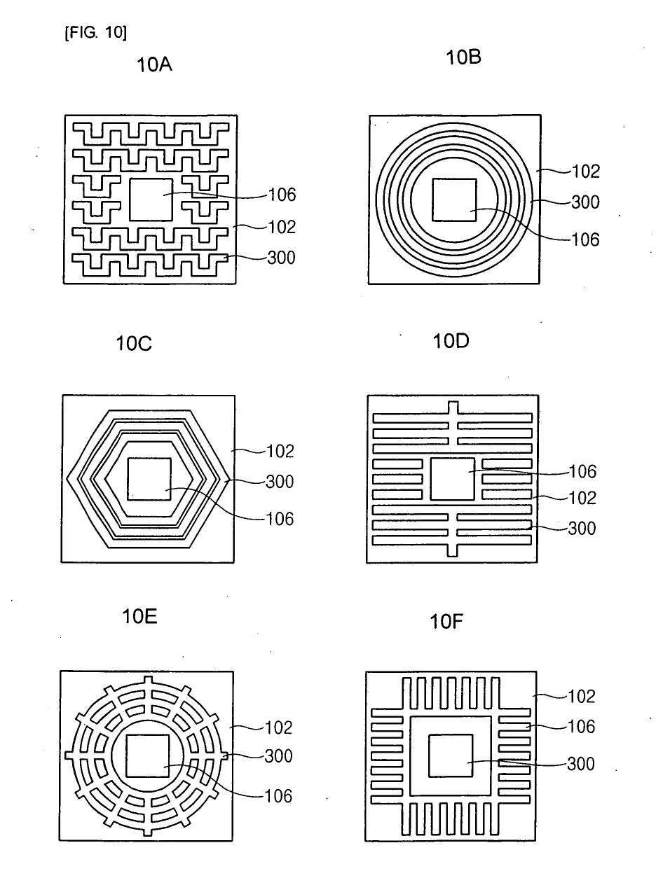

As shown in FIG. 10, the surface texturing 300 with a diffraction grating structure or mesh structure is preferably formed on the surface of the n-type nitride semiconductor layer 102 which is not overlapped with the n-type electrode 106. That is because, if the n-type electrode 106 is formed to be overlapped with the surface texturing 300 with a diffraction grating structure, the contact surface of the n-type electrode 106 has roughness due to the surface texturing. Accordingly, the resistance of electric current flowing into the n-type nitride semiconductor layer 102 through the n-type electrode 106 increases, thereby deteriorating electrical characteristics.

On the lower surface of the p-type nitride semiconductor layer 104, a p-type electrode 107 is formed.

Although not being shown, an adhesive layer is preferably positioned on the interface between the p-type nitride semiconductor layer 104 and the p-type electrode 107, in order to enhance the adherence between the p-type nitride semiconductor layer 104 and the p-type electrode 107. Such an adhesive layer can increase the effective carrier concentration of the p-type nitride semiconductor layer. Therefore, the adhesive layer is preferably formed of metal which first reacts with components of the compound composing the p-type nitride semiconductor layer, except for nitrogen.

On the lower surface of the p-type electrode 107, a supporting substrate (not shown) is preferably formed so as to support the vertically-structured nitride semiconductor LED. On the interface between the p-type electrode and the supporting substrate, an adhesive layer (not shown) is also provided so as to enhance the adherence between the p-type electrode and the supporting substrate.

According to the vertically-structured nitride semiconductor LED, the surface texturing with a diffraction grating structure or mesh structure is formed on the surface of the n-type nitride semiconductor layer, so that the distance between the patterns of the surface texturing can be minimized. Accordingly, the problems in the related art, in which some of the light emitted from the active layer is totally reflected to thereby reduce the external quantum efficiency, can be solved.

Since the external quantum efficiency of the nitride semiconductor light emitting diode can be significantly improved in the present invention, the nitride semiconductor light emitting diode and a product using the nitride semiconductor light emitting diode can be significantly improved in quality.

Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents.

What is claimed is:

1. A vertically-structured nitride semiconductor light emitting diode comprising:
an n-type electrode;
an n-type nitride semiconductor layer that is formed on the lower surface of the n-type electrode and on which surface texturing with a diffraction grating structure is formed, the diffraction grating structure composed of more than one line;
an active layer that is formed on the lower surface of the n-type nitride semiconductor layer;
a p-type nitride semiconductor layer that is formed on the lower surface of the active layer; and
a p-type electrode that is formed on the lower surface of the p-type nitride semiconductor layer.

2. The vertically-structured nitride semiconductor light emitting diode according to claim 1,
Wherein the line of the diffraction grating structure formed on the surface of the n-type nitride semiconductor layer is composed of any one line selected from a group composed of a straight line, a curved line, and a single closed curve.

3. The vertically-structured nitride semiconductor light emitting diode according to claim 1,
wherein the width of the end portion of the line composing the diffraction grating structure is the same as or larger than the wavelength of a light emitting source which is emitted by the active layer.

4. The vertically-structured nitride semiconductor light emitting diode according to claim 1,
wherein the n-type electrode is not overlapped with the surface texturing with a diffraction grating structure.

5. The vertically-structured nitride semiconductor light emitting diode according to claim 4,
wherein the n-type electrode is positioned in the center of the n-type nitride semiconductor layer.

6. A vertically-structured nitride semiconductor light emitting diode comprising:
an n-type electrode;
an n-type nitride semiconductor layer that is formed on the lower surface of the n-type electrode and on which surface texturing with a mesh structure, where more than two lines intersect each other at more than one point, is formed;
an active layer that is formed on the lower surface of the n-type nitride semiconductor layer;
a p-type nitride semiconductor layer that is formed on the lower surface of the active layer; and
a p-type electrode that is formed on the lower surface of the p-type nitride semiconductor layer.

7. The vertically-structured nitride semiconductor light emitting diode according to claim 6,
wherein the line of the mesh structure formed on the surface of the n-type nitride semiconductor layer is composed of any one line selected from a group composed of a straight line, a curved line, and a single closed curve.

8. The vertically-structured nitride semiconductor light emitting diode according to claim 6,
wherein the width of the end portion of the line composing the mesh structure is the same as or larger than the wavelength of a light emitting source which is emitted by the active layer.

9. The vertically-structured nitride semiconductor light emitting diode according to claim 6,
wherein the n-type electrode is not overlapped with the surface texturing with a mesh structure.

10. The vertically-structured nitride semiconductor light emitting diode according to claim 9,
wherein the n-type electrode is positioned in the center of the n-type nitride semiconductor layer.

11. The vertically-structured nitride semiconductor light emitting diode according to claim 1 or 6 further including
a contact layer that is formed on the interface between the p-type nitride semiconductor layer and the p-type electrode.

12. The vertically-structured nitride semiconductor light emitting diode according to claim 1 or 6 further including
a supporting substrate that is formed on the lower surface of the p-type electrode.

13. The vertically-structured nitride semiconductor light emitting diode according to claim 12 further including
a contact layer that is formed on the interface between the p-type electrode and the supporting substrate.
